(19) United States
(12) Patent Application Publication
(10) Pub. No.: US 2025/0357417 A1
(43) Pub. Date: Nov. 20, 2025

(54) BONDING APPARATUS, BONDING METHOD AND ARTICLE MANUFACTURING METHOD

(71) Applicant: CANON KABUSHIKI KAISHA, Tokyo (JP)

(72) Inventors: KENICHIRO MORI, Tochigi (JP); KAZUHIKO MISHIMA, Tochigi (JP)

(21) Appl. No.: 19/188,992

(22) Filed: Apr. 24, 2025

(30) Foreign Application Priority Data
May 15, 2024 (JP) 2024-079714

(51) Int. Cl. H01L 23/00

(52) U.S. Cl. CPC H01L 24/74; H01L 24/80; H01L 2224/74; H01L 2224/8003; H01L 2224/80895; H01L 2224/80896

(57) ABSTRACT

A bonding apparatus that performs a bonding operation of bonding a bonding object to a bonding target object, including a driving unit configured to perform driving such that the bonding object is bonded to the bonding target object, and a control unit configured to control the bonding operation such that a bonded shape of the bonding object after the bonding object is bonded to the bonding target object achieves a predetermined distortion shape.

### BACKGROUND

### Field of the Disclosure

The present disclosure relates to a bonding apparatus, a bonding method and an article manufacturing method.

### Description of the Related Art

Japanese Patent Laid-Open No. 2022-169798 proposes a technique of, when bonding a die (such as a chip or a semiconductor chip) as a bonding object to a substrate (bonding target object), bonding the die to the substrate with the die bent into a downward convex shape.

In the conventional technique, by bonding the die to the substrate with the die bent, bonding reliability can be improved. However, by bending the die, when it is bonded to a flat substrate, a shape error occurs in the die, and bonding accuracy between the die and the substrate decreases.

### SUMMARY

The present disclosure provides a technique advantageous in bonding reliability and bonding accuracy.

According to one aspect of the present disclosure, there is provided a bonding apparatus that performs a bonding operation of bonding a bonding object to a bonding target object, including a driving unit configured to perform driving such that the bonding object is bonded to the bonding target object, and a control unit configured to control the bonding operation such that a bonded shape of the bonding object after the bonding object is bonded to the bonding target object achieves a predetermined distortion shape.

Further aspects of the present disclosure will become apparent from the following description of exemplary embodiments with reference to the attached drawings.

### BRIEF DESCRIPTION OF THE DRAWINGS

FIG. 1 is a view schematically showing the arrangement of a bonding apparatus according to one or more aspects of the present disclosure;

FIGS. 2A and 2B are views for explaining a bonding distortion occurring when bonding a die to a wafer with the die bent;

FIG. 3 is a flowchart for explaining a bonding operation in the bonding apparatus shown in FIG. 1;

FIG. 4 is a view showing an example of the sensitivity representing the relationship among die information, a bonding control condition, and a bonding distortion;

FIG. 5 is a view showing an example of the specific configuration of a bonding head;

FIGS. 6A to 6C are views showing an example of the specific configuration of the bonding head;

FIGS. 7A and 7B are views for explaining a bonding method according to one or more aspects of the present disclosure;

FIGS. 8A and 8B are views for explaining a bonding method according to one or more aspects of the present disclosure; and

FIGS. 9A to 9C are views for explaining a bonding method according to one or more aspects of the present disclosure.

### DESCRIPTION OF THE EMBODIMENTS

Hereinafter, embodiments will be described in detail with reference to the attached drawings. Note, the following embodiments are not intended to limit the scope of the claimed disclosure. Multiple features are described in the embodiments, but limitation is not made to an disclosure that requires all such features, and multiple such features may be combined as appropriate. Furthermore, in the attached drawings, the same reference numerals are given to the same or similar configurations, and redundant description thereof is omitted.

A description will be given below assuming that a bonding object is a separated die including a semiconductor element, and a bonding target object is a die including a semiconductor element formed on a substrate (wafer), but the bonding object and the bonding target object are not limited thereto.

The bonding target object includes, in addition to the die including the semiconductor element formed on the substrate, for example, a silicon interposer as a silicon wafer with wiring formed thereon, and a glass interposer as a glass wafer with wiring formed thereon. The bonding target object also includes an organic interposer as an organic panel (PCB) with wiring formed thereon, a wafer formed with a semiconductor element, to which some dies including semiconductor devices have already been bonded, and the like.

The bonding object includes, in addition to the separated die, for example, a stack of some already separated dies, a small piece of a material, an optical element, a MEMS, a structure, or the like. The bonding method of the bonding object and the bonding target object is also not limited. The bonding method of the bonding object and the bonding target object includes, for example, bonding using an adhesive agent, temporary bonding using a temporary adhesive agent, bonding by hybrid bonding, atomic diffusion bonding, vacuum bonding, bump bonding, and the like. In this manner, the bonding method of the bonding object and the bonding target object includes various temporary bonding methods and permanent bonding methods. A bonding step includes various processes required for each bonding method, for example, cleaning, applying an adhesive agent, activating the surface, applying pressure, heating, or the like.

Industrial application examples of the bonding apparatus as one aspect of the present disclosure are, for example, application examples described below.

The first application example is manufacturing of a stacked memory. When the bonding apparatus as one aspect of the present disclosure is applied to manufacturing of a stacked memory, the bonding object is a separated memory die, and the bonding target object is a memory die as a semiconductor element formed on a wafer. In manufacturing of a stacked memory, in general, about eight layers are stacked. Hence, in bonding of the eighth layer, the bonding target object is a substrate as the wafer to which six layers of memory dies have already been bonded. Note that the final layer may be a driver die for driving the memories.

The second application example is heterogeneous integration of a processor. The mainstream of a conventional processor is an SoC obtained by forming a logic circuit and an SRAM in one semiconductor element. To the contrary, in heterogeneous integration, respective elements are manufactured on separate wafers while applying a process optimal for each element, and bonded to manufacture a processor. This can implement cost reduction and yield improvement of the processor. When the bonding apparatus as one aspect of the present disclosure is applied to heterogeneous integration, the bonding object is a die such as an SRAM, an antenna, or a driver separated after probing. The bonding target object is a logic die as a semiconductor element formed on the wafer. Normally, different dies are sequentially bonded. Hence, the bonding objects on the bonding target object sequentially increase. For example, in a case of starting bonding from an SRAM, when bonding the die next to the SRAM, the logic wafer with the SRAM bonded thereto serves as the bonding target object.

The third application example is 2.5D bonding using a silicon interposer. The silicon interposer is a silicon wafer with wiring formed thereon. The 2.5D bonding is a method of bonding separated dies using the silicon interposer, thereby electrically bonding the dies. When the bonding apparatus as one aspect of the present disclosure is applied to die bonding to the silicon interposer, the bonding object is a separated die, and the bonding target object is a silicon interposer as a silicon wafer with wiring formed thereon. In general, a plurality of types of dies are bonded to the silicon interposer. Hence, the bonding target object also includes a silicon interposer with several dies bonded thereto.

The fourth application example is 2.1D bonding using an organic interposer or a glass interposer. The organic interposer is an organic panel (PCB substrate or CCL substrate) used as a package substrate, on which wiring is formed. The glass interposer is a glass panel with wiring formed thereon. The 2.1D bonding is a method of bonding separated dies to the organic interposer or the glass interposer, thereby electrically bonding the dies by the wiring on the interposer. When the bonding apparatus as one aspect of the present disclosure is applied to die bonding to the organic interposer, the bonding object is a separated die, and the bonding target object is an organic panel with wiring formed thereon. When the bonding apparatus as one aspect of the present disclosure is applied to die bonding to the glass interposer, the bonding object is a separated die, and the bonding target object is a glass panel with wiring formed thereon. In general, a plurality of types of dies are bonded to the organic interposer or the glass interposer. Hence, the bonding target object also includes an organic interposer or a glass interposer with several dies bonded thereto. The fifth application example is heterogeneous substrate bonding. For example, in the field of infrared image sensors, InGaAs is known as a high sensitivity material. Accordingly, if InGaAs is used for a sensor unit that receives light, and silicon capable of implementing high-speed processing is used for a logic circuit that extracts data, a high-sensitivity high-speed infrared image sensor can be manufactured. However, from InGaAs crystal, only substrates (wafers) whose diameter is as small as 4 inches are mass-produced, which is smaller than a mainstream silicon wafer having a size of 300 mm. Hence, a technique of bonding a separated InGaAs substrate to a 300-mm silicon wafer with a logic circuit formed thereon has been proposed. The bonding apparatus as one aspect of the present disclosure can also be applied to heterogeneous substrate bonding for bonding substrates made of different materials and having different sizes. When the bonding apparatus as one aspect of the present disclosure is applied to heterogeneous substrate bonding, the bonding object is a small piece of a material such as InGaAs, and the bonding target object is a substrate such as a silicon wafer with a large diameter. Note that the small piece of the material is a slice of a crystal. The piece is preferably cut into a rectangular shape.

### First Embodiment

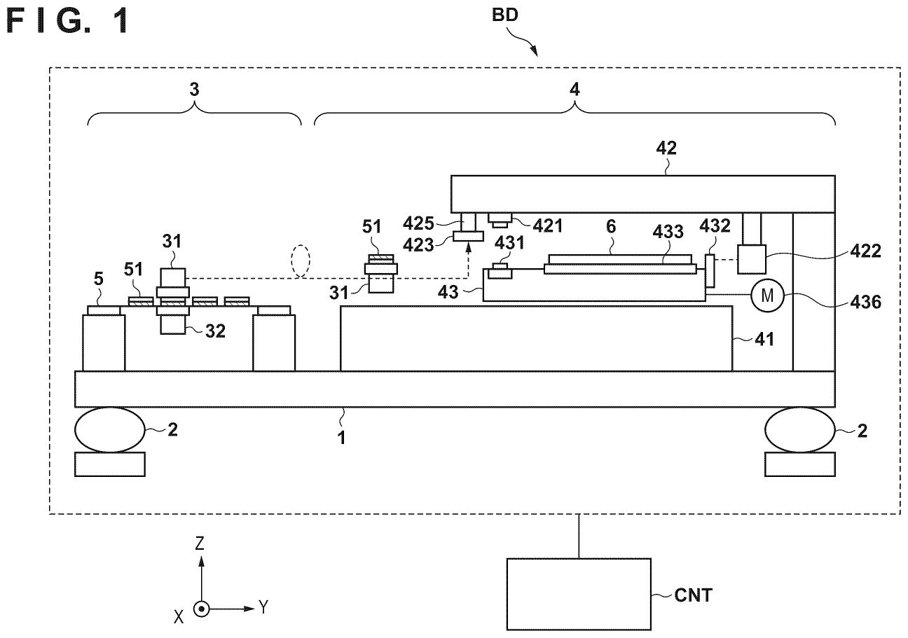

FIG. 1 is a view schematically showing the arrangement of a bonding apparatus BD as one aspect of the present disclosure. The bonding apparatus BD performs a bonding operation of bonding a separated die 51 (bonding object) to an arbitrary position (bonding target portion) on a wafer 6 (bonding target object) serving as a substrate. The die 51 is provided while being arrayed (held) on a dicing tape put on a dicing frame 5. In this specification, as shown in respective drawings, directions are indicated on an XYZ coordinate system. Typically, an XY plane is a plane parallel to the horizontal plane, and a Z-axis is an axis parallel to the vertical direction. X-, Y-, and Z-axes are examples of directions that are orthogonal to each other or cross each other.

As shown in FIG. 1, the bonding apparatus BD includes a pickup unit 3 and a bonding unit 4, which are arranged on a base 1 damped by a mount 2. In this embodiment, the pickup unit 3 and the bonding unit 4 are arranged on one base 1. However, the pickup unit 3 and the bonding unit 4 may individually be arranged on separate bases.

The bonding apparatus BD further includes a control unit CNT that controls respective units of the bonding apparatus BD. The control unit CNT is formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer (information processing apparatus) installed with a program, or a combination of all or some of them. The control unit CNT operates the bonding apparatus BD by comprehensively controlling the respective units of the bonding apparatus BD, for example, the pickup unit 3 and the bonding unit 4 in accordance with a program stored in a storage unit.

The pickup unit 3 includes a pickup head 31 and a release head 32. The pickup unit 3 peels the die 51 to be bonded to the wafer 6 from the dicing tape by the release head 32, and holds the die 51 peeled from the dicing tape by sucking it with the pickup head 31. The pickup head 31 rotates the die 51 by, for example, 180° and passes it to a bonding head 423 of the bonding unit 4.

The pickup head 31 contacts the bonding surface of the die 51. Hence, in an application to a bonding method of performing bonding by activating the surface, like hybrid bonding, it is preferable to process the surface of the pickup head 31 that comes into contact with the bonding surface. For example, it is preferable to process the surface as a highly stable surface with a diamond like carbon (DLC) coating or a fluorine coating, or reduce the contact area by processing the surface into a small shape such as a pin shape with a high density. Alternatively, a noncontact holding method like a Bernoulli chuck or a method of preventing contact with the bonding surface by holding a side surface or an edge portion of the die 51 may be used.

The bonding unit 4 functions as a bonding device configured to perform a bonding operation of bonding the die 51 to the wafer 6. The bonding unit 4 includes a stage base 41 and an upper base 42. A wafer stage 43 is mounted on the stage base 41. The wafer stage 43 is driven concerning the X direction and the Y direction by a driving mechanism 436 such as a linear motor. The driving mechanism 436 may further be configured to drive the wafer stage 43 concerning a rotation about an axis parallel to the Z direction. Instead of the driving mechanism 436 driving the wafer stage 43 concerning the rotation about the axis parallel to the Z direction, the bonding head 423 may drive the die 51 concerning the rotation about the axis parallel to the Z direction. The driving mechanism 436 functions as a positioning mechanism that changes the relative position between a wafer chuck 433 (or the wafer 6) and the bonding head 423 (or the die 51).

A die observation camera 431 is provided on the wafer stage 43. The die observation camera 431 obtains an image by capturing the die 51 held by the bonding head 423. From the image obtained by the die observation camera 431, the control unit CNT detects (specifies) the position of the feature portion of the die 51 held by the bonding head 423. A bar mirror 432 is provided on the wafer stage 43. The bar mirror 432 is used as the target of an interferometer 422.

In this embodiment, the bonding head 423 functions as the first holding unit that holds the die 51. The wafer stage 43 functions as the second holding unit that holds the wafer 6 via the wafer chuck 433.

In this embodiment, the wafer stage 43 functions as a support structure that supports the wafer chuck 433 and the die observation camera 431. The wafer stage 43 serving as the support structure includes the first end face (the left end face in FIG. 1) on the side where the die 51 is conveyed to the bonding head 423, and the second end face (the right end face in FIG. 1) on the opposite side of the first end face. The die observation camera 431 is arranged between the first end face and a virtual plane that passes through the center of the wafer stage 43 (support structure) and is parallel to the first end face. In another viewpoint, the die observation camera 431 is arranged between a predetermined position in the path to convey the die 51 to the bonding head 423 and the wafer chuck 433. This configuration is advantageous in decreasing the driving amount of the wafer stage 43 required to observe the die 51 held by the bonding head 423 by the die observation camera 431 and thus improving throughput.

A wafer observation camera 421 is provided on the upper base 42. The wafer observation camera 421 obtains an image by capturing the wafer 6 held by the wafer chuck 433 (wafer stage 43). From the image obtained by the wafer observation camera 421, the control unit CNT detects (specifies) the position of the feature portion of the wafer 6 held by the wafer chuck 433. Based on the position of the feature portion of the wafer 6, the control unit CNT also obtains the positions of a plurality of bonding target portions on the wafer.

The upper base 42 is further provided with the interferometer 422 for measuring the position of the wafer stage 43 using the bar mirror 432, and the bonding head 423 for holding the die 51 passed from the pickup head 31 and bonding it to the bonding target portion on the wafer 6.

In this embodiment, the upper base 42 functions as a support structure that supports the bonding head 423 and the wafer observation camera 421. The upper base 42 serving as the support structure includes the third end face (the left end face in FIG. 1) on the side where the die 51 is conveyed to the bonding head 423, and the fourth end face (the right end face in FIG. 1) on the opposite side of the third end face. The wafer observation camera 421 is arranged between the third end face and a virtual plane that passes through the center of the upper base 42 (support structure) and is parallel to the third end face. This configuration is advantageous in decreasing the driving amount of the wafer stage 43 required to observe the wafer 6 held by the wafer chuck 433 by the wafer observation camera 421 and thus improving throughput.

The bonding head 423 is driven concerning the Z direction by a driving mechanism 425 such as a linear motor. The driving mechanism 425 may further be configured to drive the bonding head 423 concerning the X direction and the Y direction, or may be configured to drive the bonding head 423 concerning the rotation about the axis parallel to the Z direction.

When bonding the die 51 to the bonding target portion on the wafer 6, for example, the driving mechanism 425 drives the bonding head 423 downward (−Z direction), thereby bonding the die 51 held by the bonding head 423 to the bonding target portion on the wafer 6. Alternatively, the driving mechanism 436 may drive the wafer stage 43 upward (+Z direction), thereby bonding the die 51 to the bonding target portion on the wafer 6 held by the wafer stage 43 (wafer chuck 433). Note that a driving mechanism (not shown) may drive the wafer chuck 433 upward, thereby bonding the die 51 to the bonding target portion on the wafer 6 held by the wafer chuck 433. In this manner, the driving mechanisms 425 and 436 function as a driving unit that drives at least one of the bonding head 423 (the die 51 held by the bonding head 423) and the wafer stage 43 (the wafer 6 held by the wafer stage 43) to bond the die 51 to the wafer 6.

In this embodiment, the configuration is employed in which the pickup head 31 rotates the die 51 by 180° and passes it to the bonding head 423. However, by providing one or more die holding units between the pickup head 31 and the bonding head 423, the pickup head 31 may pass the die 51 to the die holding unit, and the die holding unit may pass the die 51 to the bonding head 423. Alternatively, a driving mechanism that drives the bonding head 423 may be provided and drive the bonding head 423 such that the bonding head 423 receives the die 51 from the pickup head 31. Note that, in order to improve productivity, the bonding apparatus BD may include a plurality of pickup heads, a plurality of release heads, and a plurality of bonding heads.

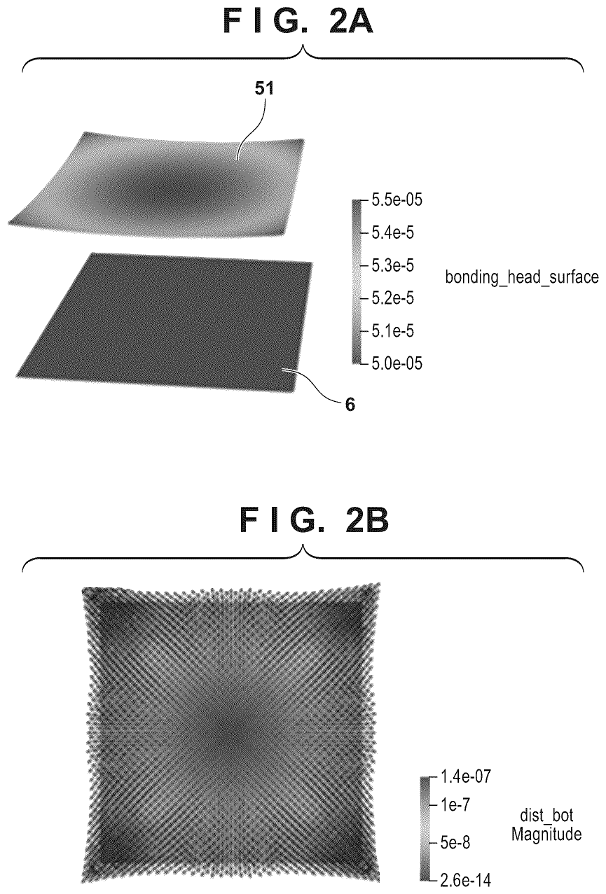

In this embodiment, when bonding the die 51 to the wafer 6, in order to improve bonding reliability, the bonding head 423 bonds the die 51 to the wafer 6 with the die 51 bent into a convex shape toward the wafer 6 side, that is, bending the die 51 into a downward convex shape. More specifically, as shown in FIG. 2A, the die 51 is bent into a shape with the protruding central portion, and brought into contact with the wafer 6. Thus, the die 51 is gradually bonded to the wafer 6 while pushing air from the central portion toward the peripheral portion. However, when bonding the die 51 to the wafer 6 with the die 51 bent, as shown in FIG. 2B, the shape of the die 51 is distorted, and a shape error (to be referred to as a “bonding distortion” hereinafter) occurs in the die 51. The bonding distortion occurring when bonding the die 51 to the wafer 6 with the die 51 bent causes a deviation in the bonding position of the die 51 with respect to the wafer 6, resulting in a decrease in bonding accuracy between the die 51 and the wafer 6.

The bonding distortion occurring when bonding the die 51 to the wafer 6 is caused by die information concerning the die 51, a bonding control condition concerning the bonding operation of bonding the die 51 to the wafer 6, or the like. The die information includes, for example, the thickness of the die 51, the size of the die 51, the material of the die 51, the stress of the semiconductor element formed on the die 51, and the like. The bonding control condition includes, for example, the bending amount and bending shape of the die 51 (the central portion relative to the peripheral portion), the relative velocity between the die 51 and the wafer 6 when bonding the die 51 to the wafer 6, and the like. The bonding control condition also includes the friction coefficient of the bonding head 423 holding the die 51, the holding force of the bonding head 423 holding the die 51, and the like.

Therefore, in this embodiment, the bonding distortion is controlled by adjusting, in accordance with the die information, the bonding control condition concerning the bonding operation of bonding the die 51 to the wafer 6. For example, the control unit CNT controls the bonding operation of bonding the die 51 to the wafer 6 such that the bonded shape of the die 51 after the die 51 is bonded to the wafer 6 achieves a predetermined distortion shape.

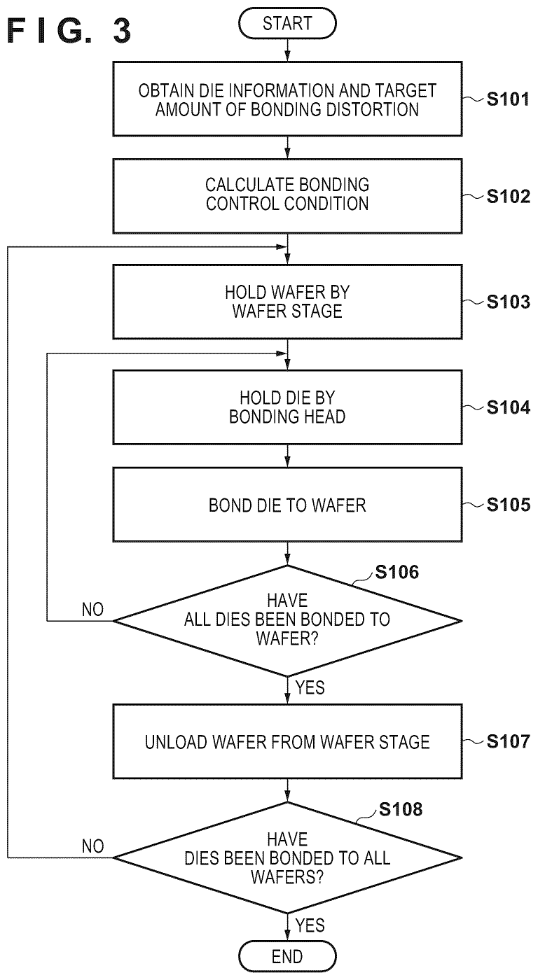

With reference to FIG. 3, the bonding operation (bonding method) in the bonding apparatus BD will be described. As described above, in this embodiment, the bonding operation includes an operation of bonding the die 51 to the wafer 6 with the die 51 bent into a downward convex shape (a convex shape toward the wafer 6 side). This bonding operation is performed by the control unit CNT comprehensively controlling the respective units of the bonding apparatus BD as described above. Note that a preparation step of preparing the die 51 and the wafer 6 and a loading step of loading the prepared die 51 and wafer 6 to the bonding apparatus BD have been performed.

In step S101, the control unit CNT obtains die information concerning the die 51, and a target amount of the bonding distortion of the die 51. As described above, die information includes at least one of the thickness of the die 51, the size of the die 51, the material of the die 51, and the stress of the semiconductor element formed on the die 51. A target amount of the bonding distortion of the die 51 includes the target shape of the bonded shape of the die 51 after the die 51 is bonded to the wafer 6, that is, a predetermined distortion shape to be intentionally generated in the die 51. In this manner, in this embodiment, the control unit CNT also functions as an obtainment unit that obtains die information and a target amount of the bonding distortion (predetermined distortion shape). Note that the control unit CNT may further obtain, in addition to die information and a target amount of the bonding distortion, wafer information concerning the wafer 6 and bonding environment (temperature, humidity, air pressure, apparatus status, or the like).

The target amount of the bonding distortion may be specified by, for example, the distortion amount of each component such as a magnification component, a third-order component, or a higher-order component, or may be specified by the distortion amount at the bonding target portion on the wafer 6.

For example, the control unit CNT obtains die information and the target amount of the bonding distortion input by the user via an input unit (user interface) of the bonding apparatus BD. However, as die information, the control unit CNT may obtain, from a die measurement unit of the bonding apparatus BD, the thickness of the die 51 and the size of the die 51 measured by the die measurement unit. Similarly, as a target amount of the bonding distortion, the control unit CNT may obtain, from a wafer measurement unit of the bonding apparatus BD, the shape of the bonding target portion (the distortion amount of the bonding target part) on the wafer 6 measured by the wafer measurement unit.

In step S102, based on the die information and the target amount of the bonding distortion obtained in step S101, the control unit CNT calculates a bonding control condition concerning the bonding operation of bonding the die 51 to the wafer 6. As described above, a bonding control condition includes at least one of the bending amount and bending shape of the die 51, the relative velocity between the die 51 and the wafer 6, the friction coefficient of the bonding head 423, and the holding force of the bonding head 423.

From the die information, the control unit CNT calculates a bonding control condition for the bonded shape of the die 51 after the die 51 is bonded to the wafer 6, that is, the bonding distortion occurring in the die 51 to achieve the target amount (for the bonded shape to achieve a predetermined distortion shape) (functions as a calculation unit). The control unit CNT calculates a bonding control condition for bringing the bonding distortion close to the target amount within constraints that can be realized by the bonding apparatus BD, for example, using an optimization method such as linear programming or a machine learning method. Note that the bonding control condition for bringing the bonding distortion close to the target amount means a bonding control condition for bringing the bonding distortion within a predetermined allowable error (margin) range with respect to the target amount of the bonding distortion.

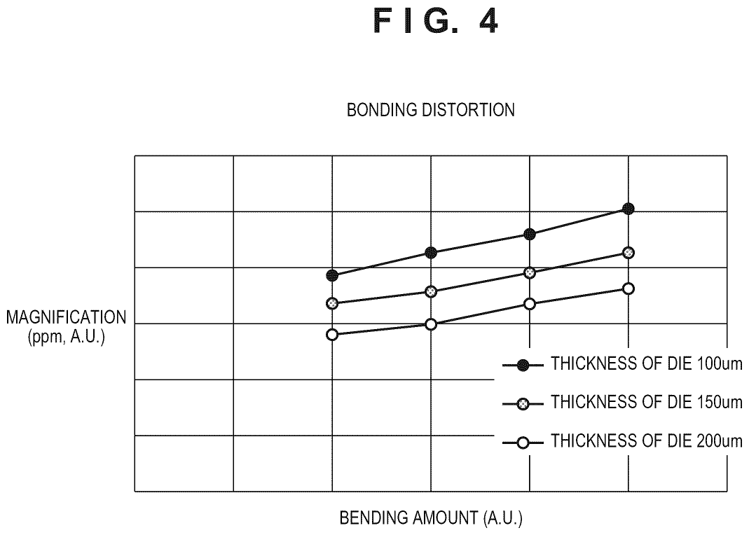

Alternatively, as shown in FIG. 4, the control unit CNT may calculate a bonding control condition for the bonding distortion occurring in the die 51 to achieve the target amount by using the sensitivity representing the relationship among die information, a bonding control condition, and a bonding distortion (amount thereof) occurring in the die 51. FIG. 4 shows the sensitivity representing the relationship among the thickness of the die 51 as the die information, the bending amount of the die 51 as the bonding control condition, and the magnification component of the bonding distortion (amount thereof) occurring in the die 51. With reference to the sensitivity shown in FIG. 4, the control unit CNT calculates, as the bonding control condition, the bending amount of the die 51 corresponding to the target amount of the magnification component of the bonding distortion from the thickness of the die 51 obtained as the die information.

In step S103, the control unit CNT causes the wafer stage 43 (wafer chuck 433) to hold the wafer 6 loaded in the bonding apparatus BD. A step of holding the wafer 6 by the wafer stage 43 includes a bonding preparation step for bonding the die 51 to the wafer 6. The bonding preparation step includes, for example, a step of measuring and positioning an alignment mark formed in the wafer 6, a step of measuring and levelling the surface position of the wafer 6, and the like.

In step S104, the control unit CNT causes the bonding head 423 to hold the die 51 loaded in the bonding apparatus BD. A step of holding the die 51 by the bonding head 423 includes a bonding preparation step for bonding the die 51 to the wafer 6. The bonding preparation step includes, for example, a step of measuring and positioning an alignment mark formed in the die 51, a step of measuring and leveling the surface position of the die 51, and the like.

In step S105, the control unit CNT bonds the die 51 held by the bonding head 423 in step S104 to the wafer 6 (bonding target portion thereof) held by the wafer stage 43 in step S103 in accordance with the bonding control condition calculated in step S102 (bonding step). In other words, the control unit CNT controls the bonding operation of bonding the die 51 to the wafer 6 such that the bonded shape of the die 51 after the die 51 is bonded to the wafer 6 achieves the predetermined distortion shape.

In step S106, the control unit CNT determines whether all of the dies 51 to be bonded to the wafer 6 have been bonded to the wafer 6 (bonding target portions thereof). In general, about 100 dies 51 are bonded to one wafer 6. If not all of the dies 51 have been bonded to the wafer 6, the process returns to step S104, and steps S104 and S105 are repeated until all of the dies 51 are bonded to the wafer 6. On the other hand, if all of the dies 51 have been bonded to the wafer 6, the process transitions to step S107.

In step S107, the control unit CNT unloads the wafer 6 with all of the dies 51 bonded thereto from the wafer stage 43 (wafer chuck 433).

In step S108, the control unit CNT determines whether the dies 51 have been bonded to all of the wafers 6 to undergo a lot process. If the dies 51 have not been bonded to all of the wafers 6, the process returns to step S103, and steps S103, S104, and S105 are repeated until the dies 51 are bonded to all of the wafers 6. On the other hand, if the dies 51 have been bonded to all of the wafers 6, the bonding operation is terminated. Note that, in general, 25 wafers 6 are processed as one lot, but there is also a case in which a plurality of lots are consecutively processed. In this case, the bonding operation of bonding the die 51 to the wafer 6 is repeated in accordance with the same bonding control condition until the wafer 6 or the die 51 (the type thereof) is changed.

As described above, according to this embodiment, when bonding the die 51 to the wafer 6 while bending the die 51 into a downward convex shape, it is possible to control the bonding operation such that the bonded shape of the die 51 after the die 51 is bonded to the wafer 6 achieves a predetermined distortion shape. Hence, in this embodiment, it is possible to suppress a deviation in the bonding position of the die 51 with respect to the wafer 6 while improving bonding reliability between the die 51 and the wafer 6. This is advantageous in bonding accuracy between the die 51 and the wafer 6.

In this embodiment, an example of bending the die 51 as the bonding object has been described. However, the wafer 6 as the bonding target object may be bent, or both the die 51 and the wafer 6 may be bent.

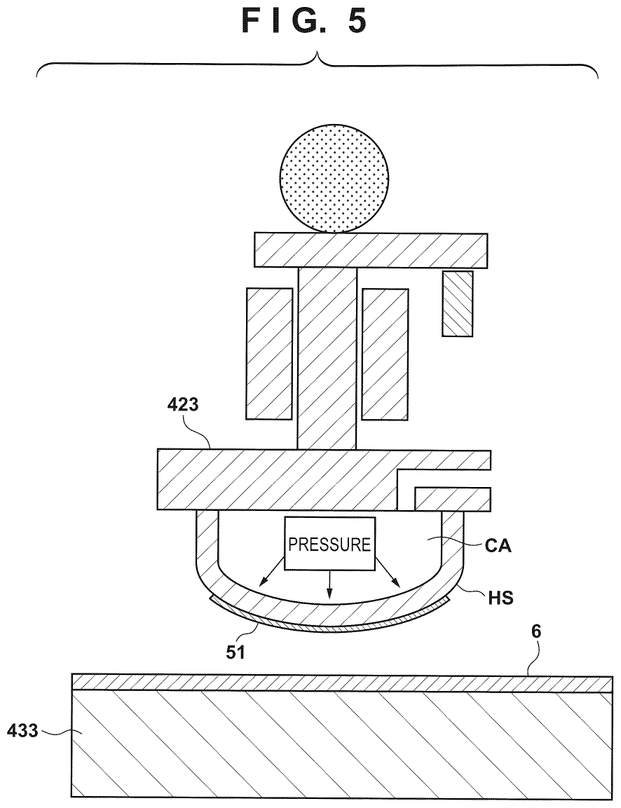

Here, with reference to FIG. 5, the specific configuration of the bonding head 423 for bending the die 51 into a downward convex shape will be described. As shown in FIG. 5, in the bonding head 423, a cavity portion CA (cavity) is formed on the back side of a holding surface HS (chuck) for holding the die 51, and a pressure adjustment mechanism (not shown) is connected to the cavity portion CA. By adjusting the pressure in the cavity portion CA via the pressure adjustment mechanism, it is possible to bend the die 51 held on the holding surface SH. More specifically, by increasing the pressure in the cavity portion CA, it is possible to bend the die 51 into a shape (downward convex shape) with the central portion protruding downward (the wafer 6 side) from the peripheral portion. By decreasing the pressure in the cavity portion CA, it is possible to bend the die 51 into a shape (upward convex shape) with the central portion protruding upward (the opposite side of the wafer 6) from the peripheral portion. Note that the shape of the holding surface SH (chuck) may be deformed in advance, and the bending shape of the die 51 may be adjusted by the pressure in the cavity portion CA. By adjusting the thickness between the holding surface SH and the cavity portion CA, it is also possible to change the bending shape of the die 51 to an R shape, a quadratic shape, or other shape. Hence, it is preferable that the configuration of the bonding head 423 is selectable (interchangeable) in accordance with the shape of the die 51 or the target bending shape of the die 51.

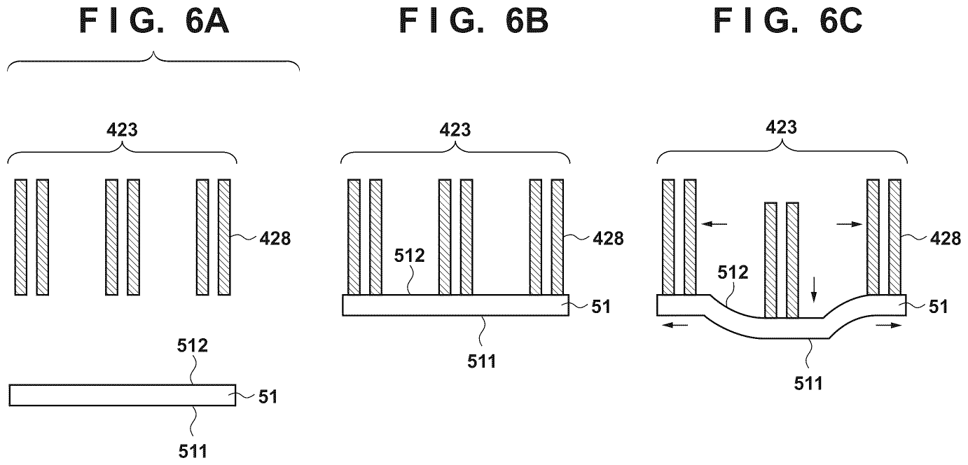

FIGS. 6A to 6C show another example of the specific configuration of the bonding head 423 for bending the die 51 into a downward convex shape. Referring to FIG. 6A, the bonding head 423 includes a plurality of vacuum suction portions 428 for chucking the die 51. As shown in FIG. 6B, the plurality of vacuum suction portions 428 function as a plurality of holding mechanisms that respectively hold a plurality of different portions of a surface 512 of the die 51 on the opposite side of a bonding surface 511 (the surface on the wafer 6 side). As shown in FIG. 6C, by driving each of the plurality of vacuum suction portions 428 in the horizontal direction (the first direction parallel to the bonding surface 511 of the die 51) and the vertical direction (the second direction crossing the first direction), it is possible to bend the die 51 into a downward convex shape. Particularly, in the bonding head 423 shown in FIGS. 6A to 6C, by driving the vacuum suction portions 428 in the horizontal direction to distort the die 51, the distortion shape of the die 51 upon bonding the die 51 to the wafer 6 can be reduced. In this embodiment, a case of holding the die 51 by vacuum suction in the bonding head 423 has been described. However, the die 51 may be held by an electrostatic force. It is also possible to adjust the bending shape and bending amount of the die 51 by individually controlling the driving directions and driving amounts of the plurality of vacuum suction portions 428. In this embodiment, the bonding head 423 is constituted by three vacuum suction portions 428 as shown in FIGS. 6A to 6C. However, in practice, by constituting the bonding head 423 by a large number of vacuum suction portions 428 arranged in an array, it is possible to precisely bend the die 51.

### Second Embodiment

With reference to FIGS. 7A and 7B, the second embodiment will be described. More specifically, a bonding method including the first bonding step of bonding a first bonding object 51a to a wafer 6, and the second bonding step of bonding a second bonding object 51b to the first bonding object 51a bonded to the wafer 6 will be described. In this embodiment as well, in order to improve bonding reliability, when bonding the first bonding object 51a or the second bonding object 51b, each of the first bonding object 51a and the second bonding object 51b is bent into a downward convex shape (a convex shape toward the wafer 6 side).

In this embodiment, first, as shown in FIG. 7A, a bonding control condition is controlled such that the bonded shape of the first bonding object 51a after the first bonding object 51a is bonded to the wafer 6 achieves a predetermined distortion shape, and the first bonding object 51a is bonded to the wafer 6. Note that the predetermined distortion shape is a bobbin shape in FIG. 7A, but the predetermined distortion shape is not limited thereto and may be a barrel shape, a shape having a magnification component, a skewed shape, a shape having a magnification difference between the vertical direction and the horizontal direction, or the like.

Then, as shown in FIG. 7B, the second bonding object 51b is bonded to the first bonding object 51a bonded to the wafer 6 (that is, the bonded object on the bonding target object). More specifically, a bonding control condition is controlled such that the bonded shape of the second bonding object 51b after the second bonding object 51b is bonded to the first bonding object 51a on the wafer matches the predetermined distortion shape controlled when bonding the first bonding object 51a, and the second bonding object 51b is bonded to the first bonding object 51a. In general, the first bonding object 51a and the second bonding object 51b are different in the thickness of the die, the size of the die, the material of the die, and the stress of the semiconductor element formed on the die. Accordingly, the bonding control condition for bonding the second bonding object 51b to the first bonding object 51a is different from the bonding control condition for bonding the first bonding object 51a to the wafer 6.

According to this embodiment, it is possible to bond the first bonding object 51a and the second bonding object 51b with a reduced deviation in the bonding position of the second bonding object 51b with respect to the first bonding object 51a while maintaining high bonding reliability.

### Third Embodiment

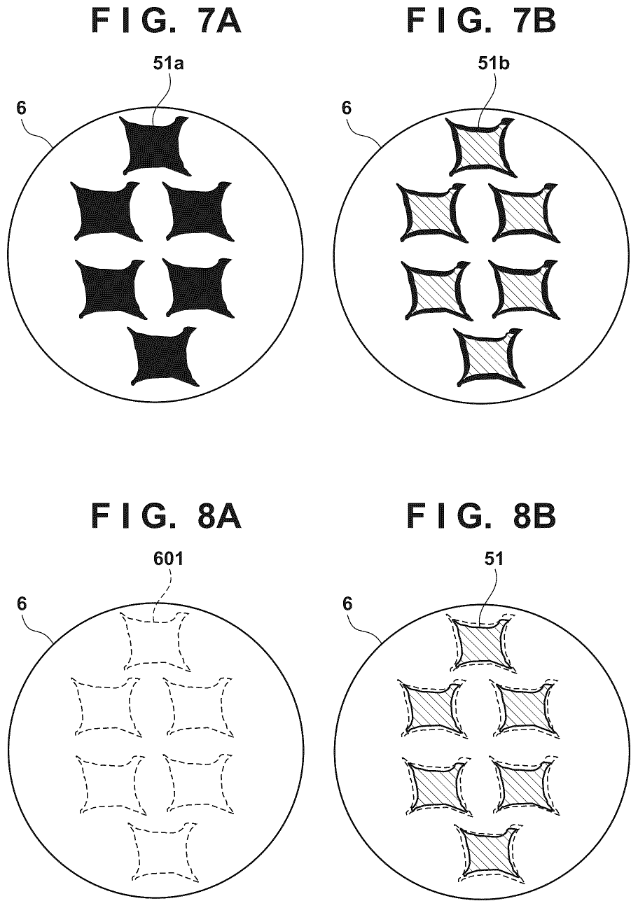

With reference to FIGS. 8A and 8B, the third embodiment will be described. More specifically, a bonding method including a formation step of forming (manufacturing) a semiconductor element 601 on a wafer 6, and a bonding step of bonding the die 51 to the semiconductor element 601 formed on the wafer 6 will be described. In this embodiment as well, in order to improve bonding reliability, when bonding the die 51, the die 51 is bent into a downward convex shape (a convex shape toward the wafer 6 side).

In this embodiment, first, as shown in FIG. 8A, the semiconductor element 601 is formed on the wafer 6 in accordance with the distortion shape of the die 51 after bonding. Note that in FIG. 8A, the distortion shape is a bobbin shape, but the distortion shape is not limited thereto and may be a barrel shape, a shape having a magnification component, a skewed shape, a shape having a magnification difference between the vertical direction and the horizontal direction, or the like. The semiconductor element 601 (shape thereof) can be distorted by a semiconductor exposure apparatus during patterning.

Then, as shown in FIG. 8B, the die 51 is bonded to the semiconductor element 601 formed on the wafer 6. More specifically, a bonding control condition is controlled such that the bonded shape of the die 51 after the die 51 is bonded to the semiconductor element 601 on the wafer matches the distortion shape (predetermined distortion shape) of the semiconductor element 601, and the die 51 is bonded to the semiconductor element 601. In other words, in this embodiment, the semiconductor element 601 is formed on the wafer 6 such that the shape of the semiconductor element 601 formed on the wafer 6 achieves the bonded shape (predetermined distortion shape) of the die 51 bonded to the semiconductor element 601 on the wafer.

According to this embodiment, it is possible to bond the semiconductor element 601 and the die 51 with a reduced deviation in the bonding position of the die 51 with respect to the semiconductor element 601 formed on the wafer 6 while maintaining high bonding reliability.

### Fourth Embodiment

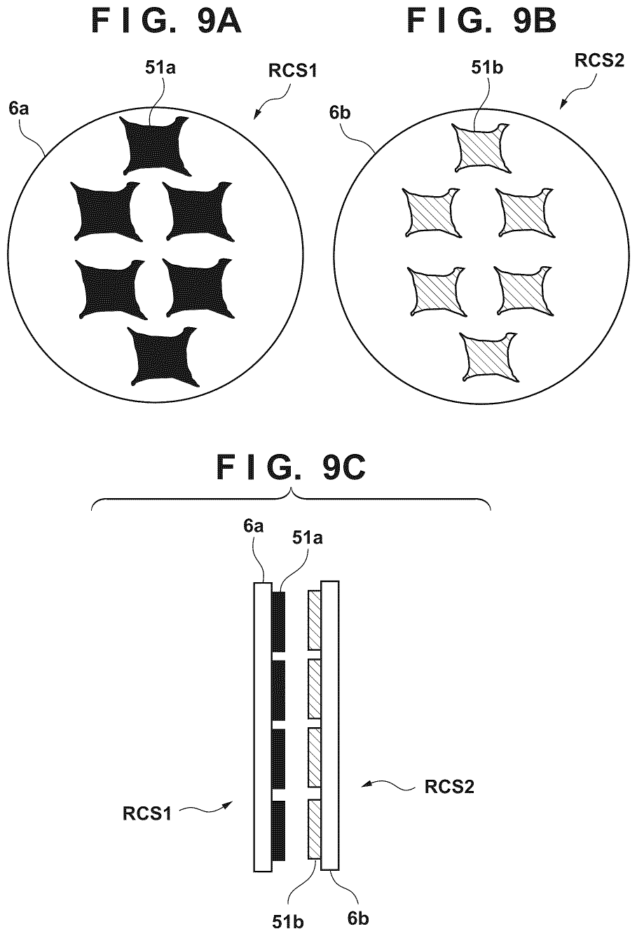

With reference to FIGS. 9A to 9C, the fourth embodiment will be described. A bonding method described in this embodiment includes three bonding steps. More specifically, a bonding method according to this embodiment includes the first bonding step of bonding a first bonding object 51a to a first substrate 6a, and the second bonding step of bonding a second bonding object 51b to a second substrate 6b. Furthermore, the bonding method according to this embodiment includes, in addition to the first bonding step and the second bonding step, the third bonding step of bonding the first substrate 6a with the first bonding object 51a bonded thereto and the second substrate 6b with the second bonding object 51b bonded thereto.

In this embodiment, first, as shown in FIG. 9A, a bonding control condition is controlled such that the bonded shape of the first bonding object 51a after the first bonding object 51a is bonded to the first substrate 6a achieves a predetermined distortion shape, and the first bonding object 51a is bonded to the first substrate 6a. Thus, a first reconstructed substrate RCS1, which is the first substrate 6a on which the first bonding objects 51a are arrayed, is manufactured. Note that the predetermined distortion shape is a bobbin shape in FIG. 9A, but the predetermined distortion shape is not limited thereto and may be a barrel shape, a shape having a magnification component, a skewed shape, a shape having a magnification difference between the vertical direction and the horizontal direction, or the like. However, since the first reconstructed substrate RCS1 is finally reversed axially symmetrically and bonded to a second reconstructed substrate RCS2 (to be described later), the predetermined distortion shape is preferably an axisymmetric shape about the reversal axis. Note that the reconstructed substrate may be in a form in which the bonding object is bonded to the substrate and sealed with a mold material, and the substrate is then removed. In this case, a step of removing the mold material deposited on the surface of the bonding object to expose the surface of the bonding object (semiconductor element surface), or the like is required.

Then, as shown in FIG. 9B, a bonding control condition is controlled such that the bonded shape of the second bonding object 51b after the second bonding object 51b is bonded to the second substrate 6b achieves a predetermined distortion shape, and the second bonding object 51b is bonded to the second substrate 6b. Here, a predetermined distortion shape is a distortion shape that matches the distortion shape controlled when bonding the first bonding object 51a to the first substrate 6a. Thus, the second reconstructed substrate RCS2, which is the second substrate 6b on which the second bonding objects 51b are arrayed, is manufactured. In general, the first bonding object 51a and the second bonding object 51b are different in the thickness of the die, the size of the die, the material of the die, and the stress of the semiconductor element formed on the die. Accordingly, the bonding control condition for bonding the second bonding object 51b to the second substrate 6b is different from the bonding control condition for bonding the first bonding object 51a to the first substrate 6a.

Then, as shown in FIG. 9C, the first reconstructed substrate RCS1 and the second reconstructed substrate RCS2 are reversed axially symmetrically and bonded to the other. More specifically, the first substrate 6a and the second substrate 6b are aligned and bonded such that the first bonding object 51a on the first substrate and the second bonding object 51b on the second substrate are bonded.

According to this embodiment, it is possible to bond the first bonding object 51a and the second bonding object 51b with a reduced deviation in the bonding position of each of the first bonding object 51a and the second bonding object 51b while maintaining high bonding reliability.

### Fifth Embodiment

A method of manufacturing an article (a semiconductor IC element, a liquid crystal display element, a MEMS, or the like) using a bonding apparatus BD in the above-described embodiment will be described. The article is manufactured through a preparation step of preparing a bonding object and a bonding target object, a bonding step of bonding the bonding object to the bonding target object using the bonding apparatus BD (bonding method (bonding operation)), and a manufacturing step of manufacturing the article by processing the bonding target object with the bonding object bonded thereto in another known process. The other known process includes probing, dicing, bonding, packaging, and the like. The article manufacturing method according to this embodiment is advantageous in at least one of the performance, quality, productivity, and production cost of the article, as compared to conventional methods.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-079714 filed on May 15, 2024, which is hereby incorporated by reference herein in its entirety.

What is claimed is:

1. A bonding apparatus that performs a bonding operation of bonding a bonding object to a bonding target object, comprising;
a driving unit configured to perform driving such that the bonding object is bonded to the bonding target object; and
a control unit configured to control the bonding operation such that a bonded shape of the bonding object after the bonding object is bonded to the bonding target object achieves a predetermined distortion shape.

2. The apparatus according to claim 1, wherein
the control unit includes
an obtainment unit configured to obtain the predetermined distortion shape, and
a calculation unit configured to calculate a control condition concerning the bonding operation for the bonded shape of the bonding object to achieve the predetermined distortion shape obtained by the obtainment unit.

3. The apparatus according to claim 2, wherein the bonding operation includes an operation of bonding the bonding object to the bonding target object with the bonding object bent into a convex shape toward a side of the bonding target object.

4. The apparatus according to claim 3, wherein the control condition includes at least one of a bending amount of the bonding object when bonding the bonding object to the bonding target object, a bending shape of the bonding object when bonding the bonding object to the bonding target object, a relative velocity between the bonding object and the bonding target object when bonding the bonding object to the bonding target object, and a holding force of the bonding object when bonding the bonding object to the bonding target object.

5. The apparatus according to claim 2, wherein the calculation unit calculates the control condition based on at least one of a thickness of the bonding object, a size of the bonding object, a material of the bonding object, and a stress of a semiconductor element formed on the bonding object.

6. The apparatus according to claim 1, further comprising:
a first holding unit configured to hold the bonding object; and
a second holding unit configured to hold the bonding target object,
wherein the driving unit drives at least one of the first holding unit and the second holding unit.

7. The apparatus according to claim 6, wherein, when bonding the bonding object to the bonding target object, the first holding unit bends the bonding object into a convex shape toward a side of the bonding target object.

8. The apparatus according to claim 7, wherein the first holding unit
includes a plurality of holding mechanisms that respectively hold a plurality of different portions of a surface of the bonding object on an opposite side of a bonding surface on a side of the bonding target object, and
bends the bonding object into a convex shape toward the side of the bonding target object by driving each of the plurality of holding mechanisms in a first direction parallel to the bonding surface and a second direction crossing the first direction.

9. The apparatus according to claim 1, wherein
the bonding object is a die including a semiconductor element, and
the bonding target object is a substrate.

10. The apparatus according to claim 1, wherein
the bonding object is a die including a semiconductor element, and
the bonding target object is a semiconductor element formed on a substrate.

11. The apparatus according to claim 1, wherein
the bonding object is a first bonding object bonded to a first reconstructed substrate, and
the bonding target object is a second bonding object bonded to a second reconstructed substrate different from the first reconstructed substrate.

12. A bonding method of bonding a bonding object to a bonding target object, comprising:
preparing the bonding object and the bonding target object; and
bonding the bonding object to the bonding target object such that a bonded shape of the bonding object after the bonding object is bonded to the bonding target object achieves a predetermined distortion shape.

13. A bonding method comprising:
bonding a first bonding object to a bonding target object such that a bonded shape of the first bonding object after the first bonding object is bonded to the bonding target object achieves a predetermined distortion shape; and
bonding a second bonding object to the first bonding object such that a bonded shape of the second bonding object after the second bonding object is bonded to the first bonding object on the bonding target object achieves the predetermined distortion shape.

14. A bonding method comprising:
forming a semiconductor element on a substrate; and
bonding a bonding object to the semiconductor element such that a bonded shape of the bonding object after the bonding object is bonded to the semiconductor element on the substrate achieves a predetermined distortion shape,
wherein in the forming, the semiconductor element is formed on the substrate such that a shape of the semiconductor element formed on the substrate achieves the predetermined distortion shape.

15. A bonding method comprising:
bonding a first bonding object to a first substrate such that a bonded shape of the first bonding object after the first bonding object is bonded to the first substrate achieves a predetermined distortion shape;
bonding a second bonding object to a second substrate such that a bonded shape of the second bonding object after the second bonding object is bonded to the second substrate achieves the predetermined distortion shape; and
bonding the first substrate and the second substrate such that the first bonding object on the first substrate and the second bonding object on the second substrate are bonded.

16. An article manufacturing method comprising:
preparing a bonding object and a bonding target object;
bonding the bonding object to the bonding target object using a bonding apparatus that performs a bonding operation of bonding a bonding object to a bonding target object, comprising;
a driving unit configured to perform driving such that the bonding object is bonded to the bonding target object; and
a control unit configured to control the bonding operation such that a bonded shape of the bonding object after the bonding object is bonded to the bonding target object achieves a predetermined distortion shape; and
manufacturing an article by processing the bonding target object with the bonding object bonded thereto.
